(19) United States
(12) Patent Application Publication
(10) Pub. No.: US 2019/0332198 A1
(43) Pub. Date: Oct. 31, 2019

(54) DISPLAY DEVICE, ELECTRONIC DEVICE AND METHOD OF MANUFACTURING DISPLAY DEVICE

(71) Applicant: SHENZHEN ROYOLE TECHNOLOGIES CO., LTD., SHENZHEN, GUANGDONG (CN)

(72) Inventor: Wenhui Li, Shenzhen, Guangdong (CN)

(21) Appl. No.: 16/310,216

(22) PCT Filed: Dec. 26, 2016
(86) PCT No.: PCT/CN2016/112096

§ 371 Date: Dec. 14, 2018

(51) Int. Cl. G06F 3/041; H01R 12/62; H05K 1/14; H05K 3/36

(52) U.S. Cl. CPC G06F 3/041; H01R 12/62; H05K 1/147; G06F 2203/04103; H05K 2201/10128; H05K 2201/10151; G06F 2203/04102; H05K 3/361

(57) ABSTRACT

A display device, an electronic device, and a method of manufacturing the display device are disclosed. The display device includes a display screen, a touch screen, and a flexible circuit board. A first circuit layer is formed in a display area of the display screen. A first connecting terminal and a second connecting terminal are formed in a non-display area of the display screen. The first circuit layer is connected to the first connecting terminal. The touch screen comprises a first side and a second side opposite to the first side. A second circuit layer and a third connecting terminal are formed on the first side. The second circuit layer corresponds to the display area. The third connecting terminal is connected to the second connecting terminal and the second circuit layer. The flexible circuit board is connected to the first connecting terminal and the second connecting terminal.

### CROSS-REFERENCE TO RELATED APPLICATION

The present application is a National Phase entry under 35 U.S.C. § 371 of International Application PCT/CN2016/112096, filed Dec. 26, 2016, the content of which is incorporated herein by reference in its entirety, and published as WO 2018/119572 on Jul. 5, 2018, not in English.

### FIELD

The present disclosure relates to a field of display technology, and particularly to a display device, an electronic device, and a method of manufacturing the display device.

### BACKGROUND

In the related art, a display screen with a touch screen needs to connect the touch screen to a flexible circuit board of the touch screen first, and then attach the touch screen with the flexible circuit board to the display screen, and furthermore, after the touch screen is attached to the display screen, the flexible circuit board of the touch screen also needs to be connected to the printed circuit board again. Thus the manufacture of the display screen has more procedures and the manufacturing cost is increased.

### SUMMARY

The present disclosure aims to at least solve one of the technical problems in the related art. To this purpose, the present disclosure needs to provide a display device, an electronic device and a method of manufacturing the display device.

The display device of embodiments of the present disclosure includes a display screen, a touch screen and a flexible circuit board. The display screen has a display area and a non-display area. The display area is provided with a first circuit layer. The non-display area is provided with a first connecting terminal and a second connecting terminal. The first connecting terminal and the second connecting terminal are arranged at a same surface of the display screen and spaced apart. The first circuit layer is connected with the first connecting terminal. The touch screen includes a first surface and a second surface opposite to the first surface. The touch screen is attached to the display screen through the first surface. The first surface is provided with a second circuit layer and a third connecting terminal. The second circuit layer is corresponding to the display area. The third connecting terminal connects the second connecting terminal and the second circuit layer. The flexible circuit board is connected to a side of the display screen and connected to the first connecting terminal and the second connecting terminal.

In the display device of embodiments of the present disclosure, the flexible circuit board is connected to the first connecting terminal and the second connecting terminal, thus realizing a purpose of the display screen and the touch screen sharing the same flexible circuit board. In this way, during the manufacture of the display device, it is only required to attach the touch screen to the display screen, and connect the flexible circuit board to the display screen, so that the manufacture procedures of the display device can be reduced and the manufacture cost of the display device can be decreased.

In an embodiment, the display screen includes a protective layer, and the protective layer covers the first circuit layer and separates the first circuit layer from the second circuit layer.

In an embodiment, the display device includes a printed circuit board. The flexible circuit board has a first end connected to a side of the display screen and a second end connected to the printed circuit board.

In an embodiment, the flexible circuit board is manufactured through chip-on-film technology

In an embodiment, the touch screen is a flexible touch screen.

In an embodiment, the display device includes a first bonding portion, a second bonding portion and a third bonding portion. The first bonding portion connects the second connecting terminal and the third connecting terminal, the second bonding portion connects the flexible circuit board and the first connecting terminal, and the third bonding portion connects the flexible circuit board and the second connecting terminal.

In an embodiment, the first bonding portion is an anisotropic conductive film, the second bonding portion is an anisotropic conductive film, and the third bonding portion is an anisotropic conductive film.

The electronic device according to embodiments of the present disclosure includes the display device of any one of the above embodiments.

In the electronic device of embodiments of the present disclosure, the flexible circuit board is connected with the first connecting terminal and the second connecting terminal, thus realizing the purpose of the display screen and the touch screen sharing the same flexible circuit board. In this way, during the manufacture of the display device, it is only required to attach the touch screen to the display screen, and connect the flexible circuit board to the display screen, so that the manufacture procedures of the display device can be reduced and the manufacture cost of the display device can be decreased.

The method of manufacturing the display device according to embodiments of the present disclosure includes:
providing a display screen, the display screen including a display area and a non-display area, the display area being provided with a first circuit layer, the non-display area being provided with a first connecting terminal and a second connecting terminal, the first connecting terminal and the second connecting terminal being arranged at a same surface of the display screen and spaced apart, and the first circuit layer being connected with the first connecting terminal;
providing a touch screen, the touch screen including a first surface and a second surface opposite to the first surface, the first surface being provided with a second circuit layer and a third connecting terminal, and the third connecting terminal being connected to the second circuit layer;
orienting the first surface towards a surface, provided with the second connecting terminal, of the display screen and attaching the touch screen to the display screen, the second circuit layer being corresponding to the display area, and the third connecting terminal being connected to the second connecting terminal; and
connecting the flexible circuit board to a side of the display screen and connecting the flexible circuit board to the first connecting terminal and the second connecting terminal.

In the method of manufacturing the display device in embodiments of the present disclosure, the flexible circuit board is connected to the first connecting terminal and the second connecting terminal, thus realizing a purpose of the display screen and the touch screen sharing the same flexible circuit board. In this way, during the manufacture of the display device, it is only required to attach the touch screen to the display screen, and connect the flexible circuit board to the display screen, so that the manufacture procedures of the display device can be reduced and the manufacture cost of the display device can be decreased.

In an embodiment, the method of manufacturing the display device further includes forming a protective layer on the display screen, the protective layer covering the first circuit layer so as to separate the first circuit layer from the second circuit layer.

In an embodiment, the method of manufacturing the display device further includes providing a printed circuit board and connecting an end of the flexible circuit board to the printed circuit board.

In an embodiment, the method of manufacturing the display device further includes:

providing a first bonding portion and using the first bonding portion to connect the second connecting terminal and the third connecting terminal;

providing a second bonding portion and using the second bonding portion to connect the flexible circuit board and the first connecting terminal; and

providing a third bonding portion and using the third bonding portion to connect the flexible circuit board and the second connecting terminal.

Additional aspects and advantages of embodiments of present disclosure will be given in part in the following descriptions, become apparent in part from the following descriptions, or be learned from the practice of the embodiments of the present disclosure.

### BRIEF DESCRIPTION OF THE DRAWINGS

These and other aspects and advantages of embodiments of the present disclosure will become apparent and more readily appreciated from the following descriptions made with reference to the drawings, in which:

FIG. 1 is a schematic plan view of a display device of embodiments of the present disclosure;

FIG. 2 is a schematic section view of a display device of embodiments of the present disclosure;

FIG. 3 is a partial schematic plan view of a display device of embodiments of the present disclosure;

FIG. 4 is a schematic plan view of a display screen of a display device of embodiments of the present disclosure;

FIG. 5 is a schematic plan view of a touch screen of a display device of embodiments of the present disclosure;

FIG. 6 is another schematic plan view of a touch screen of a display device of embodiments of the present disclosure;

### REFERENCE NUMERALS OF MAIN ELEMENTS

display device 10;
printed circuit board 11;
display screen 12;
display area 121, first circuit layer 122, electrode a, electrode b, connecting line c, non-display area 123, first connecting terminal 124, first conductive sheet 124a, second connecting terminal 125, second conductive sheet 125a, protective layer 126;
first bonding portion 13;
touch screen 14;
first surface 141, second surface 142, second circuit layer 143, third connecting terminal 144, third conductive sheet 144a;
flexible circuit board 16.

### DETAILED DESCRIPTION

The embodiments of the present disclosure are described in detail below, and the examples of the embodiments are illustrated in the drawings, wherein the same or similar reference numerals are used to refer to the same or similar elements or elements having the same or similar functions. The embodiments described below with reference to the accompanying drawings are illustrative, which intend to explain the present disclosure and cannot be construed to limit the present disclosure.

In the specification, it is to be understood that terms such as “central,” “longitudinal,” “lateral,” “length,” “width,” “thickness,” “upper,” “lower,” “front,” “rear,” “left,” “right,” “vertical,” “horizontal,” “top,” “bottom,” “inner,” “outer,” “clockwise,” and “counterclockwise” should be construed to refer to the orientation as then described or as shown in the drawings under discussion. These relative terms are for convenience of description and do not require that the present disclosure be constructed or operated in a particular orientation. In addition, terms such as “first” and “second” are used herein for purposes of description and are not intended to indicate or imply relative importance or significance or to imply the number of indicated technical features. Thus, the feature defined with “first” and “second” may comprise one or more of this feature. In the description of the present disclosure, “a plurality of” means two or more than two, unless specified otherwise.

In the present disclosure, unless specified or limited otherwise, the terms “mounted,” “connected,” “coupled” and the like are used broadly, and may be, for example, fixed connections, detachable connections, or integral connections; may also be mechanical or electrical connections; may also be direct connections or indirect connections via intervening structures; may also be inner communications or interaction relationship of two elements, which can be understood by those skilled in the art according to specific situations.

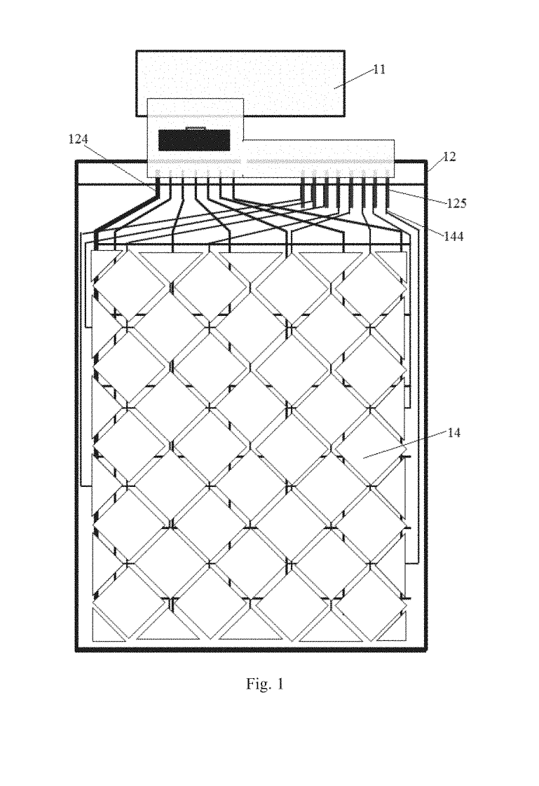

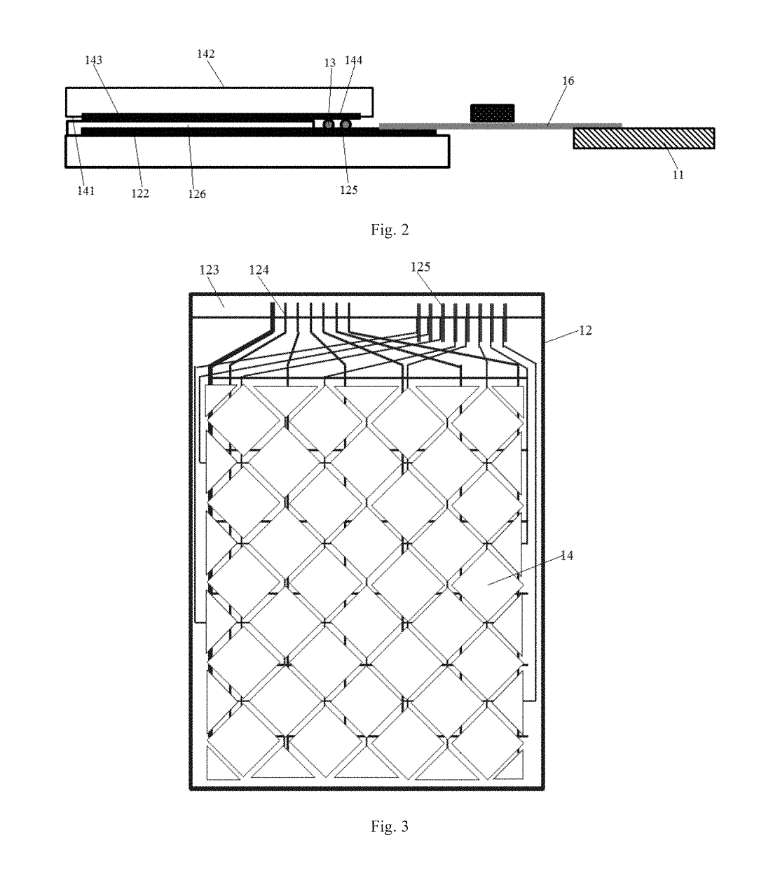

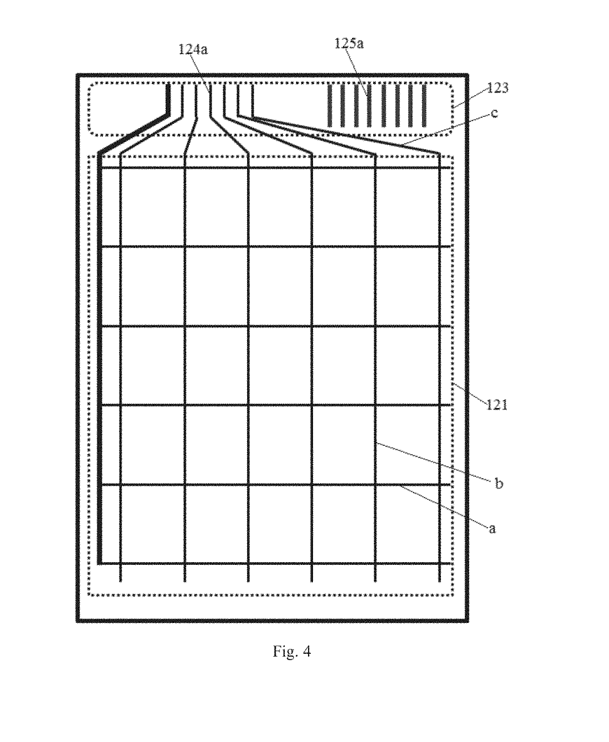

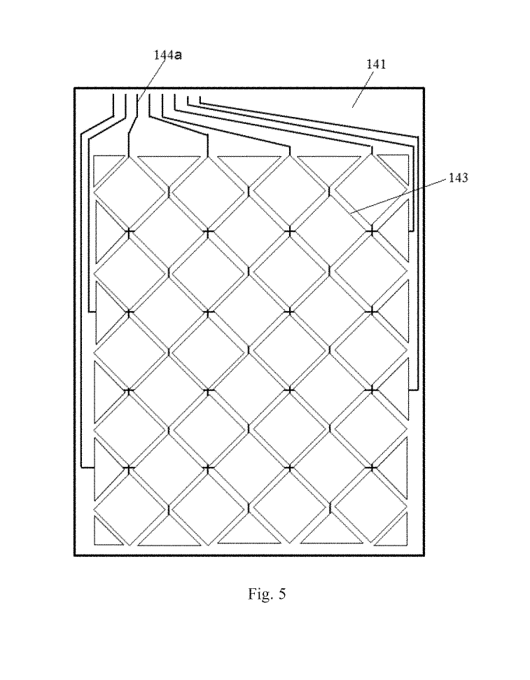

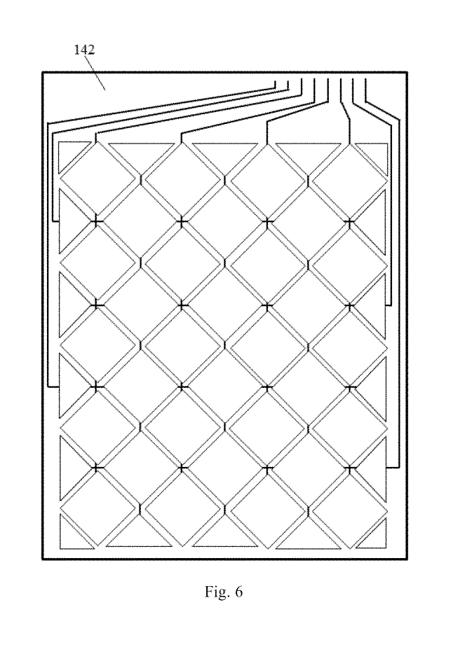

Referring to FIG. 1 to FIG. 6 together, a display device 10 includes a display screen 12, a touch screen 14 and a flexible circuit board 16.

The display screen 12 has a display area 121 provided with a first circuit layer 122. The display screen 12 has a non-display area 123 provided with a first connecting terminal 124 and a second connecting terminal 125. The first connecting terminal 124 and the second connecting terminal 125 are spaced apart and arranged at a same surface of the display screen 12. The first circuit layer 122 is connected with the first connecting terminal 124.

The touch screen 14 includes a first surface 141 and a second surface 142 opposite to the first surface 141. The touch screen 14 is attached to the display screen 14 through the first surface 141. The first surface 141 is provided with a second circuit layer 143 and a third connecting terminal 144. The second circuit layer 143 is corresponding to the display area 121. The third connecting terminal 144 connects the second connecting terminal 125 and the second circuit layer 143. The flexible circuit board 16 is connected to a side of the display screen 12 and connected to the first connecting terminal 124 and the second connecting terminal 125.

In the display device 10 of embodiments of the present disclosure, the flexible circuit board 16 is connected to the first connecting terminal 124 and the second connecting terminal 125, thus realizing a purpose of the display screen 12 and the touch screen 14 sharing the same flexible circuit board 16. In this way, during the manufacture of the display device 10, it is only required to attach the touch screen 14 to the display screen 12, and connect the flexible circuit board 16 to the display screen 12, so that the manufacture procedures of the display device 10 can be reduced and the manufacture cost of the display device 10 can be decreased.

Specifically, in an example, the display screen 12 can be a liquid-crystal display screen or an organic-light-emitting-diode display screen.

In an embodiment, the first circuit layer 122 includes a plurality of electrodes a and a plurality of electrodes b crossing the plurality of electrodes a. The plurality of electrodes a are distributed at regular intervals along a direction of Y axis and the plurality of electrodes b are distributed at regular intervals along a direction of X axis. Thus, the sensitivity of the first circuit layer 122 is higher and the accuracy of the signal transmission of the display screen 12 is improved.

It could be understood that the display area 121 of the display screen 12 has an area larger than an area of the non-display area 123 of the display screen 12, in order to make full use of the display screen 12 and improve the display effect of the display screen 12.

In an embodiment, the first circuit layer 122 includes a plurality of connecting lines c and the first connecting terminal 124 includes a plurality of first conductive sheets 124a arranged at intervals. The plurality of first conductive sheets 124a are connected with the plurality of connecting lines c correspondingly so as to realize the connection between the first connecting terminal 124 and the first circuit layer 122.

The second connecting terminal 125 includes a plurality of second conductive sheets 125a arranged at intervals, and the third connecting terminal 144 includes a plurality of third conductive sheets 144a arranged at intervals. The plurality of second conductive sheets 125a are connected with the plurality of third conductive sheets 144a correspondingly so as to realize the connection between the second connecting terminal 125 and the third connecting terminal 144.

In this way, the plurality of connecting lines c are connected to the plurality of first conductive sheets 124a correspondingly so that a larger signal transmission area exists between the first circuit layer 122 and the first connecting terminal 124 and accuracy of the connection between the first circuit layer 122 and the first connecting terminal 124 is improved. Meanwhile, the plurality of second conductive sheets 125a are connected to the plurality of third conductive sheets 144a correspondingly so that a larger signal transmission area exists between the second connecting terminal 125 and the third connecting terminal 144 and accuracy of the connection between the second connecting terminal 125 and the third connecting terminal 144 is improved, thus ensuing accuracy of the connection between the display screen 12 and the touch screen 14.

Specifically, the plurality of first conductive sheets 124a are arranged in a straight line, the plurality of second conductive sheets 125a are arranged in a straight line, and the plurality of third conductive sheets 144a are arranged in a straight line. In this way, the conductive sheets are distributed more evenly and occupy less space.

The first circuit layer 122 is made of a transparent conductive material, the first conductive sheet 124a is made of a transparent conductive material, the second conductive sheet 125a is made of a transparent conductive material, and the third conductive sheet 144a is made of a transparent conductive material. In this way, the conductive sheets have better conductivity and a wide material source, and are easy to manufacture. The transparent conductive material for example includes ITO.

In an embodiment, the display screen 12 includes a protective layer 126, and the protective layer 126 covers the first circuit layer 122 and separates the first circuit layer 122 from the second circuit layer 143.

In this way, the protective layer 126 has a protective function for the first circuit layer 122 having a conductive property, which can prevent the first circuit layer 122 from being damaged due to being in an exposed state, so that service life of the first circuit layer 122 is prolonged. Meanwhile, the protective layer 126 can prevent the first circuit layer 122 and the second circuit layer 143 from interfering with each other and then influencing the signal transmission, thus ensuring respective signal transmission of the display screen 12 and the touch screen 14.

In an example, the protective layer 126 can be made of an insulating material.

In an embodiment, the display device 10 includes a printed circuit board 11. The flexible circuit board 16 has a first end connected to a side of the display screen 12 and a second end connected to the printed circuit board 11.

In this way, the connection between the flexible circuit board 16 and the printed circuit board 11 is realized in a relatively simple manner, and the printed circuit board 11 can serve as a transmission medium for the display device 10 and an external control apparatus.

In an embodiment, the flexible circuit board 16 is manufactured through chip-on-film (COF) technology. As a result, the flexible circuit board 16 has better signal transmission performance.

In an embodiment, the touch screen 14 is a flexible touch screen. As a result, the touch screen 14 is bendable and has better operational performance, a wide application scope and lower power consumption.

In an embodiment, the display device 10 includes a first bonding portion 13, a second bonding portion (not illustrated in the figures) and a third bonding portion (not illustrated in the figures). The first bonding portion 13 connects the second connecting terminal 125 and the third connecting terminal 144. The second bonding portion connects the flexible circuit board 16 and the first connecting terminal 124. The third bonding portion connects the flexible circuit board 16 and the second connecting terminal 125.

In this way, the stability of the connection between the second connecting terminal 125 and the third connecting terminal 144 is ensured by means of the first bonding portion 13, the stability of the connection between the flexible circuit board 16 and the first connecting terminal 124 is ensured by means of the second bonding portion, and the stability of the connection between the flexible circuit board 16 and the second connecting terminal 125 is ensured by means of the third bonding portion.

In an embodiment, the first bonding portion 13 is an anisotropic conductive film (ACF), the second bonding portion is an anisotropic conductive film, and the third bonding portion is an anisotropic conductive film. As a result, the bonding portions have better bonding performance and a wide source.

An electronic device according to embodiments of the present disclosure includes the display device 10 of any one of the above embodiments.

In the electronic device of embodiments of the present disclosure, the flexible circuit board 16 is electrically connected with the first connecting terminal 124 and the second connecting terminal 125, thus realizing the purpose of the display screen 12 and the touch screen 14 sharing the same flexible circuit board 16. In this way, during the manufacture of the display device 10, it is only required to attach the touch screen 14 to the display screen 12, and connect the flexible circuit board 16 to the display screen 12, so that the manufacture procedures of the display device 10 can be reduced and the manufacture cost of the display device 10 can be decreased.

It could be understood that the electronic device can be an electronic device having a touch function, such as a mobile phone, a tablet computer or a notebook computer.

The method of manufacturing the display device 10 according to embodiments of the present disclosure includes:
providing a display screen 12, the display screen 12 including a display area 121 and a non-display area 123, the display area 121 being provided with a first circuit layer 122, the non-display area 123 being provided with a first connecting terminal 124 and a second connecting terminal 125, the first connecting terminal 124 and the second connecting terminal 125 being spaced apart and arranged at a same surface of the display screen 12, and the first circuit layer 122 being connected with the first connecting terminal 124;
providing a touch screen 14, the touch screen 14 including a first surface 141 and a second surface 142 opposite to the first surface 141, the first surface 141 being provided with a second circuit layer 143 and a third connecting terminal 144, and the third connecting terminal 144 being connected to the second circuit layer 143;
orienting the first surface 141 towards a surface, provided with the second connecting terminal 125, of the display screen 12 and attaching the touch screen 14 to the display screen 12, the second circuit layer 143 being corresponding to the display area 121, and the third connecting terminal 144 being connected to the second connecting terminal 125; and
connecting the flexible circuit board 16 to a side of the display screen 12 and electrically connecting the flexible circuit board 16 to the first connecting terminal 124 and the second connecting terminal 125.

In the method of manufacturing the display device in embodiments of the present disclosure, the flexible circuit board 16 is electrically connected to the first connecting terminal 124 and the second connecting terminal 125, thus realizing a purpose of the display screen 12 and the touch screen 14 sharing the same flexible circuit board 16. In this way, during the manufacture of the display device 10, it is only required to attach the touch screen 14 to the display screen 12, and connect the flexible circuit board 16 to the display screen 12, so that the manufacture procedures of the display device 10 can be reduced and the manufacture cost of the display device 10 can be decreased.

In an embodiment, the method of manufacturing the display device further includes: forming a protective layer 126 on the display screen 12, in which the protective layer 126 covers the first circuit layer 122 so as to separate the first circuit layer 122 from the second circuit layer 143.

In this way, the protective layer 126 has a protective function for the first circuit layer 122 having a conductive property, which can prevent the first circuit layer 122 from being damaged due to being in an exposed state, so that service life of the first circuit layer 122 is prolonged. Meanwhile, the protective layer 126 can prevent the first circuit layer 122 and the second circuit layer 143 from interfering with each other and then influencing the signal transmission, thus ensuring accuracy of signal transmission between the display screen 12 and the touch screen 14.

It is to be noted that forming the protective layer 126 is performed before attaching the touch screen 14 to the display screen 12.

In an embodiment, the method of manufacturing the display device further includes: providing a printed circuit board 11 and connecting an end of the flexible circuit board 16 to the printed circuit board 11.

Thus, the connection between the flexible circuit board 16 and the printed circuit board 11 is realized in a simpler manner, and the printed circuit board 11 can serve as a transmission medium for the display device 10 and an external control apparatus.

In an embodiment, the method of manufacturing the display device further includes:
providing a first bonding portion 13 and using the first bonding portion 13 to connect the second connecting terminal 125 and the third connecting terminal 144;
providing a second bonding portion and using the second bonding portion to connect the flexible circuit board 16 and the first connecting terminal 124; and
providing a third bonding portion and using the third bonding portion to connect the flexible circuit board 16 and the second connecting terminal 125.

In this way, the stability of the connection between the second connecting terminal 125 and the third connecting terminal 144 is ensured by means of the first bonding portion 13, the stability of the connection between the flexible circuit board 16 and the first connecting terminal 124 is ensured by means of the second bonding portion, and the stability of the connection between the flexible circuit board 16 and the second connecting terminal 125 is ensured by means of the third bonding portion.

Specifically, after the non-display area 123 of the display screen 12 is provided with the first connecting terminal 124 and the second connecting terminal 125, the first bonding portion 13 can be connected to an end of the second connecting terminal 125, the touch screen 14 can be attached to the display screen 12 and the third connecting terminal 144 can be connected to the first bonding portion 13, the second bonding portion can be connected to the first connecting terminal 124, the third bonding portion can be connected to another end of the second connecting terminal 125, and the flexible circuit board 16 can be connected to both of the second bonding portion and the third bonding portion.

It is to be indicated that the above explanation for the embodiments of the display device 10 is also applicable to the method of manufacturing the display device of embodiments of the present disclosure, which is not elaborated herein in order to avoid redundancy.

In the present disclosure, unless specified or limited otherwise, a structure in which a first feature is “on” or “below” a second feature may include an embodiment in which the first feature is in direct contact with the second feature, and may also include an embodiment in which the first feature and the second feature are not in direct contact with each other, but are contacted via an additional feature formed therebetween. Furthermore, a first feature “on,” “above,” or “on top of” a second feature may include an embodiment in which the first feature is right or obliquely “on,” “above,” or “on top of” the second feature, or just means that the first feature is at a height higher than that of the second feature; while a first feature “below,” “under,” or “on bottom of” a second feature may include an embodiment in which the first feature is right or obliquely “below,” “under,” or “on bottom of” the second feature, or just means that the first feature is at a height lower than that of the second feature.

Various embodiments and examples are provided in the following description to implement different structures of the present disclosure. In order to simplify the present disclosure, certain elements and settings will be described. However, these elements and settings are only by way of example and are not intended to limit the present disclosure. In addition, reference numerals may be repeated in different examples in the present disclosure. This repeating is for the purpose of simplification and clarity and does not refer to relations between different embodiments and/or settings. Furthermore, examples of different processes and materials are provided in the present disclosure. However, it would be appreciated by those skilled in the art that other processes and/or materials may be also applied.

Reference throughout this specification to “an embodiment,” “some embodiments,” “illustrative embodiments,” “an example,” “a specific example,” or “some examples,” means that a particular feature, structure, material, or characteristic described in connection with the embodiment or example is included in at least one embodiment or example of the present disclosure. Thus, the appearances of the phrases in various places throughout this specification are not necessarily referring to the same embodiment or example of the present disclosure. Furthermore, the particular features, structures, materials, or characteristics may be combined in any suitable manner in one or more embodiments or examples.

Although explanatory embodiments have been shown and described, it would be appreciated by those skilled in the art that changes, alternatives, variation and modifications can be made in the embodiments without departing from principles and spirit of the present disclosure. The scope of the present disclosure is defined by the claims and its equivalents.

1. A display device, comprising:
a display screen, the display screen comprising a display area and a non-display area, the display area being provided with a first circuit layer, the non-display area being provided with a first connecting terminal and a second connecting terminal, the first connecting terminal and the second connecting terminal being arranged at a same surface of the display screen and spaced apart, and the first circuit layer being connected with the first connecting terminal;
a touch screen, the touch screen comprising a first surface and a second surface opposite to the first surface, the touch screen being attached to the display screen through the first surface, the first surface being provided with a second circuit layer and a third connecting terminal, the second circuit layer being corresponding to the display area, and the third connecting terminal connecting the second connecting terminal and the second circuit layer; and
a flexible circuit board, the flexible circuit board being connected to a side of the display screen and connected with the first connecting terminal and the second connecting terminal.

2. The display device according to claim 1, wherein the display screen comprises a protective layer, and the protective layer covers the first circuit layer and separates the first circuit layer from the second circuit layer.

3. The display device according to claim 1, wherein the display device comprises a printed circuit board, and the flexible circuit board has a first end connected to a side of the display screen and a second end connected to the printed circuit board.

4. The display device according to claim 1, wherein the flexible circuit board is manufactured through chip-on-film technology.

5. The display device according to claim 1, wherein the touch screen is a flexible touch screen.

6. The display device according to claim 1, wherein the display device comprises a first bonding portion, a second bonding portion and a third bonding portion, the first bonding portion connects the second connecting terminal and the third connecting terminal, the second bonding portion connects the flexible circuit board and the first connecting terminal, and the third bonding portion connects the flexible circuit board and the second connecting terminal.

7. The display device according to claim 6, wherein each of the first bonding portion, the second bonding portion and the third bonding portion is an anisotropic conductive film.

8. An electronic device, comprising a display device, wherein the display device comprises:
a display screen, the display screen comprising a display area and a non-display area, the display area being provided with a first circuit layer, the non-display area being provided with a first connecting terminal and a second connecting terminal, the first connecting terminal and the second connecting terminal being arranged at a same surface of the display screen and spaced apart, and the first circuit layer being connected with the first connecting terminal;
a touch screen, the touch screen comprising a first surface and a second surface opposite to the first surface, the touch screen being attached to the display screen through the first surface, the first surface being provided with a second circuit layer and a third connecting terminal, the second circuit layer being corresponding to the display area, and the third connecting terminal connecting the second connecting terminal and the second circuit layer; and
a flexible circuit board, the flexible circuit board being connected to a side of the display screen and connected with the first connecting terminal and the second connecting terminal.

9. A method for manufacturing a display device, comprising:
providing a display screen, the display screen comprising a display area and a non-display area, the display area being provided with a first circuit layer, the non-display area being provided with a first connecting terminal and a second connecting terminal, the first connecting terminal and the second connecting terminal being arranged at a same surface of the display screen and spaced apart, and the first circuit layer being connected with the first connecting terminal;
providing a touch screen, the touch screen comprising a first surface and a second surface opposite to the first surface, the first surface being provided with a second circuit layer and a third connecting terminal, and the third connecting terminal being connected to the second circuit layer;
orienting the first surface towards a surface, provided with the second connecting terminal, of the display screen and attaching the touch screen to the display screen, the second circuit layer being corresponding to the display area, and the third connecting terminal being connected to the second connecting terminal; and
connecting the flexible circuit board to a side of the display screen, and connecting the flexible circuit board to the first connecting terminal and the second connecting terminal.

10. The method according to claim 9, further comprising:
forming a protective layer on the display screen, the protective layer covering the first circuit layer so as to separate the first circuit layer from the second circuit layer.

11. The method according to claim 9, further comprising:
providing a printed circuit board and connecting an end of the flexible circuit board to the printed circuit board.

12. The method according to claim 9, further comprising:
providing a first bonding portion and connecting the second connecting terminal and the third connecting terminal by using the first bonding portion;
providing a second bonding portion and connecting the flexible circuit board and the first connecting terminal by using the second bonding portion;
providing a third bonding portion and connecting the flexible circuit board and the second connecting terminal by using the third bonding portion.

13. The electronic device according to claim 8, wherein the display screen comprises a protective layer, and the protective layer covers the first circuit layer and separates the first circuit layer from the second circuit layer.

14. The electronic device according to claim 8, wherein the display device comprises a printed circuit board, and the flexible circuit board has a first end connected to a side of the display screen and a second end connected to the printed circuit board.

15. The electronic device according to claim 8, wherein the flexible circuit board is manufactured through chip-on-film technology.

16. The electronic device according to claim 8, wherein the touch screen is a flexible touch screen.

17. The electronic device according to claim 8, wherein the display device comprises a first bonding portion, a second bonding portion and a third bonding portion, the first bonding portion connects the second connecting terminal and the third connecting terminal, the second bonding portion connects the flexible circuit board and the first connecting terminal, and the third bonding portion connects the flexible circuit board and the second connecting terminal.

18. The electronic device according to claim 17, wherein each of the first bonding portion, the second bonding portion and the third bonding portion is an anisotropic conductive film.
